(19) United States
(12) Patent Application Publication
(10) Pub. No.: US 2026/0088251 A1
(43) Pub. Date: Mar. 26, 2026

(54) System and Method for Atomic Layer Etching with Uniformity Control Mechanisms

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/898,599

(22) Filed: Sep. 26, 2024

(51) Int. Cl. H01J 37/32; H01J 37/34

(52) U.S. Cl. CPC H01J 37/32174; H01J 37/3211; H01J 37/347; H01J 37/3476; H01J 2237/3341; H01J 2237/3346

(57) ABSTRACT

Disclosed herein are systems and methods for an ALE process with uniformity control mechanisms. The ALE process comprises multiple cycles, with each cycle including a surface modification step followed by a sputtering step. A plasma source includes both a center coil and an edge coil. The system allows for optional configurations during the sputtering step across different ALE cycles, enabling independent activation or deactivation of the center and edge coils. This flexibility provides a mechanism for adjusting the etching rate at the center and edges of the substrate, thereby compensating for non-uniformities, such as thickness variations, in incoming substrates. The system controller is configured to generate a process recipe based on incoming substrate data as well as an output specification, ensuring that the etching process meets the desired performance requirements.

### FIELD OF INVENTION

The present invention relates to plasma-based semiconductor fabrication processes, and more specifically, to systems and methods for atomic layer etching (ALE) that enable improved control over substrate etching uniformity. The invention provides selectable sputtering step options during ALE cycles to compensate for non-uniformities in incoming substrates, such as variations in targeted layer thickness, while maintaining the precision and uniformity inherent to ALE.

### BACKGROUND

Reactive ion etching (RIE) is a predominant technology in semiconductor manufacturing. In RIE, various species, including neutrals, radicals, and ions, concurrently influence the etching process. A key characteristic of RIE is the synergistic interaction between ion and neutral fluxes, which significantly enhances the etching rate. This synergistic effect was first described by Coburn and Winters in “Ion-and electron-assisted gas-surface chemistry-an important effect in plasma etching,” published in J. Appl. Phys., vol. 50, pages 3189-3196 (1979). They reported increased silicon etching rates when using an argon ion beam, a XeF2 neutral beam, and their combination. Effective RIE necessitates the presence of both ion and neutral fluxes to exploit this synergy. However, in modern etching processes, balancing these fluxes, particularly for etching high aspect ratio structures with dimensions shrinking to the nanometer scale, is increasingly complex. Achieving uniform results across 300 mm wafers and consistent repeatability in production pose additional challenges.

ALE has been developed to address the limitations of RIE. The ALE process system has evolved from the RIE process system, with less stringent requirements for achieving uniformity on a 300 mm wafer. However, ALE has unique requirements due to the nature of its process steps. An overview of ALE technology is presented by Karanik et al. in “Overview of atomic layer etching in the semiconductor industry” (J. Vac. Sci. Technol. A33, pages 020802 1-14, 2015), and further discussed by Lill in “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and material removal. The modification creates a thin reactive layer with a defined thickness, which is easier to remove than the unmodified material. The removal step eliminates this modified layer while preserving the underlying substrate, thus resetting the surface for subsequent cycles. Material removal can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process. The anisotropic ALE process, as described in U.S. Pat. No. 10,727,073 to Tan et al., demonstrates the technology's versatility.

However, despite ALE's intrinsic uniformity, there are cases where incoming substrates exhibit non-uniformities, such as thickness variations in targeted layers, due to prior process steps. These variations can impact the overall performance of the final device if left unaddressed. In sophisticated process controls, there is a growing need for systems that can compensate for such non-uniformities without compromising the precision of the etching process.

Existing ALE process systems may lack the flexibility to address substrate-specific variations dynamically during the ALE process. While conventional ALE cycles are uniform by design, they do not account for the need to tailor the etching process to compensate for non-uniformities across different regions of the substrate.

Therefore, there is a need for an ALE process system that offers greater flexibility in controlling the sputtering step to address substrate non-uniformities, ensuring that the final etched result meets the stringent requirements of advanced semiconductor manufacturing processes.

### SUMMARY

The present invention relates to a system and method for performing ALE with enhanced control over process uniformity, particularly in response to incoming substrate non-uniformities. In some embodiments, the invention provides a system controller that manages the ALE process across multiple cycles, where each cycle includes a surface modification step and a sputtering step. While ALE is inherently uniform due to its self-limiting nature, in certain processes, compensating for non-uniformities, such as variations in the thickness of targeted layers, becomes necessary to achieve desired outcomes.

To address such non-uniformities, in some implementations, the system incorporates selectable options for the sputtering step. These options enable the system controller to adjust the etching characteristics across different regions of the substrate. For example, the system controller may selectively activate or deactivate a center coil or an edge coil during the sputtering step to focus the etching process on specific areas, such as enhancing etching at the center or edges of the substrate. This flexibility allows for precise control over layer removal and can be tailored for each ALE cycle based on the needs of the incoming substrate.

In some embodiments, the system controller determines the appropriate option for the sputtering step by analyzing data related to the substrate's non-uniformities. This ensures that the process can compensate for thickness variations or other deviations across the substrate, improving the overall uniformity of the final etched layer. These selectable options, tailored for each cycle, provide a critical mechanism for addressing sophisticated process control requirements without compromising the intrinsic uniformity of the ALE process itself.

The invention thus offers enhanced adaptability in ALE, allowing for fine-tuned process adjustments to address substrate-specific variations while maintaining the uniformity that is characteristic of ALE.

### BRIEF DESCRIPTIONS OF THE DRAWINGS

The clarity of the embodiments is enhanced by referring to the following description in conjunction with the accompanying drawings:

FIG. 1: Illustrates an exemplary ALE process system.

FIG. 2: Depicts a schematic of a transformer coupled plasma (TCP) source implemented with a center and an edge coil.

FIG. 3A: Demonstrates a first implementation of a TCP source where the center and edge coils are driven by a single RF power generator with an RF power divider.

FIG. 3B: Highlights a schematic of a second implementation of the TCP source where the center and edge coils are driven by separate RF power generators for independent control.

FIG. 4: Presents a flowchart of an embodiment of the ALE process, incorporating non-uniformity control mechanisms.

FIG. 5: Presents a flowchart of an exemplary ALE process with selectable sputtering steps.

Table 1: Showcases an example of selectable configurations for the sputtering step in the ALE process, used to address substrate non-uniformities.

### DETAILED DESCRIPTIONS

To foster a comprehensive understanding, this description elaborates on specific implementations of the current invention. While specific details are provided for elucidation, adjustments and variations that align with the following claims are deemed acceptable. Some established procedures and components are selectively detailed to underscore the unique facets of the invention.

### Terms Used

Anisotropic ALE (or simply ALE): Refers to a highly precise etching process in semiconductor manufacturing that removes material layer by layer at the atomic scale. ALE operates in cycles, typically including a surface modification step, where the surface is chemically altered, followed by a sputtering step, where ion bombardment removes the modified layer. This process provides control over etch depth and anisotropic profiles.
Bias Unit: Refers to a unit generates a controlled voltage to accelerate ions toward the substrate held by an electrostatic chuck (ESC). The bias unit creates an electric field that enhances ion bombardment, offering control of ion energy and directionality during the etching process.
Chamber: An enclosed environment where semiconductor manufacturing processes, such as etching or deposition, take place.
Chuck: A component used to hold and secure the substrate during semiconductor manufacturing processes.
ESC (Electrostatic Chuck): A type of chuck that uses electrostatic forces to secure the substrate in place during processing, providing uniform clamping and stability.
Gas Distribution Unit: In some implementations, this unit distributes process gases across the substrate. The gas can be introduced through injectors, a showerhead configuration, or side injection mechanisms to enhance gas flow and distribution.
Gas Source: The supply of process gases used in vacuum chambers. In some embodiments, a gas box controls and regulates the gas flow under controlled pressure conditions.
Plasma Source: In some implementations, this source generates plasma for processes such as etching or deposition. Examples include inductively coupled plasma (ICP), transformer coupled plasma (TCP), and capacitively coupled plasma (CCP).
Process System: Refers to the integrated equipment used in semiconductor manufacturing to perform processes such as deposition, etching, or surface modification.
Pulsing: A technique where RF power is delivered in pulses instead of continuously, improving control over plasma energy and enhancing process precision and uniformity.
Reactive Ion Etching (RIE): A plasma-based etching technique that combines physical ion bombardment with chemical reactions to remove material from the substrate. RIE offers anisotropic etching, critical for complex microfabrication.
Resonator: A device that resonates at a specific RF frequency, often used in RF impedance matching applications within semiconductor processing equipment.
RF Power Generator: A device that produces RF energy used to sustain plasma in processes such as etching and deposition.
Substrate: The base material, typically a silicon wafer, upon which semiconductor devices are fabricated.
System Controller: The central control unit that coordinates and manages operations within a process system, ensuring efficient and precise execution of semiconductor processes.
Tailored Waveform Generator: In some embodiments, this generator produces custom electrical waveforms to optimize ion energy distribution and improve etching or deposition performance.
Transmission Line (in RF): A conductor designed to efficiently carry RF signals in semiconductor processes, such as etching or deposition, with minimal loss or distortion.
Vacuum Chamber: An enclosed environment where air and other gases are removed to create a low-pressure setting, essential for precision semiconductor manufacturing.
Window: A non-conductive component in a vacuum chamber that separates the plasma generation region from external elements while allowing electromagnetic waves, such as RF or microwave energy, to pass through.

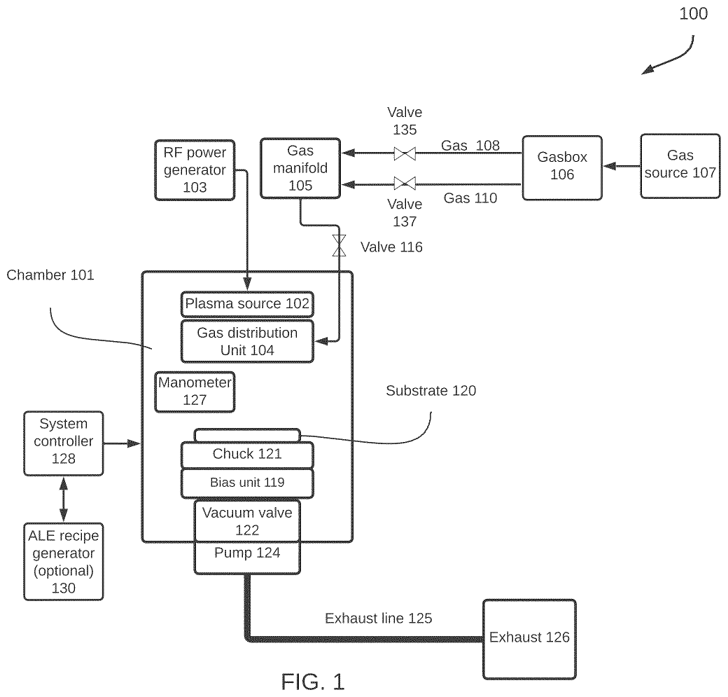

Referring to FIG. 1, a gas distribution unit 104 draws gases from a gasbox 106 via a gas manifold 105. The gas distribution unit 104 can be configured as a showerhead or an injector, depending on the design. The gas manifold 105 mixes the gases prior to their introduction into the process chamber 101. The gasbox 106 typically comprises components such as mass flow controllers (MFCs), gas pressure regulators, particle filters, gas mixers, and safety sensors. Two valves, 135 and 137, are positioned between the gasbox 106 and the manifold 105, controlling the flow of gases 108 and 110, respectively. While two gas lines are depicted, this is merely exemplary, and additional gas lines may be used in some implementations. A valve 116 is installed between the manifold 105 and the gas distribution unit 104 to regulate the flow of gases into the chamber 101. The gasbox 106 is connected to a gas source 107.

Within the lower portion of the chamber 101, a chuck 121 supports a substrate 120 during the process. The chuck 121 is typically an electrostatic chuck (ESC) designed for etching processes. To increase ion energy during etching, particularly for high-aspect-ratio structures, a bias unit 119 is employed when the chamber's plasma is ignited. Depending on the design, the bias unit 119 can be an RF power generator connected to the chuck 121 via a blocking capacitor or a tailored waveform generator specifically configured for this purpose.

Gases, including reaction by-products, are evacuated from the chamber 101 by a pump 124. A vacuum valve 122 located upstream of the pump regulates the gas removal rate. The evacuated gases are directed to an exhaust 126 via an exhaust line 125. The chamber's pressure is controlled by balancing the injection and removal rates of gases, with a proportional-integral-derivative (PID) control loop adjusting the pressure based on readings from a manometer 127.

An ALE process operates cyclically, typically involving two gases delivered in two distinct steps: a surface modification step and a sputtering step, often referred to as two half-cycles that complete one ALE cycle. The surface modification step is commonly referred to as step A, while the sputtering step is referred to as step B.

The operations of the process system 100 are coordinated by a system controller 128, which comprises a computer and various software modules. The system controller 128 includes an ALE recipe generator 130, which is utilized to generate a process recipe for the ALE process by taking into considerations of the incoming substrate in addition to output specification. The recipe generator 130 is a software module of the system controller 128. The incoming substrate data include but are not limited to critical dimensions and targeted layer thickness across the substrate.

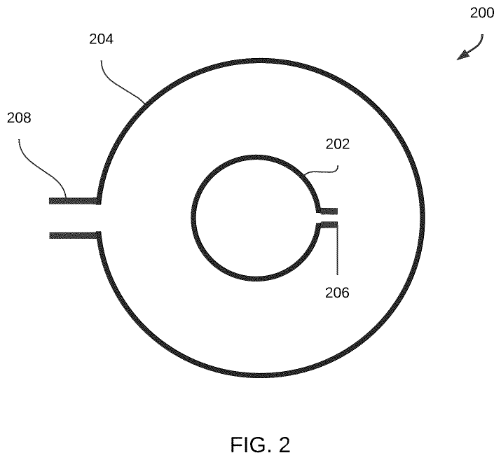

Referring to FIG. 2, a top view of two concentric coils 200 is shown to improve plasma uniformity within the chamber 101. The plasma source includes a center coil 202 and an edge coil 204. The center coil 202 is coupled to an RF power generator via a pair of connectors 206, while the edge coil 204 is coupled to the same or a different RF power generator via another pair of connectors 208. Although only a single coil turn is shown in FIG. 2, the coils may include multiple turns, and various geometries may be utilized, as known in the art.

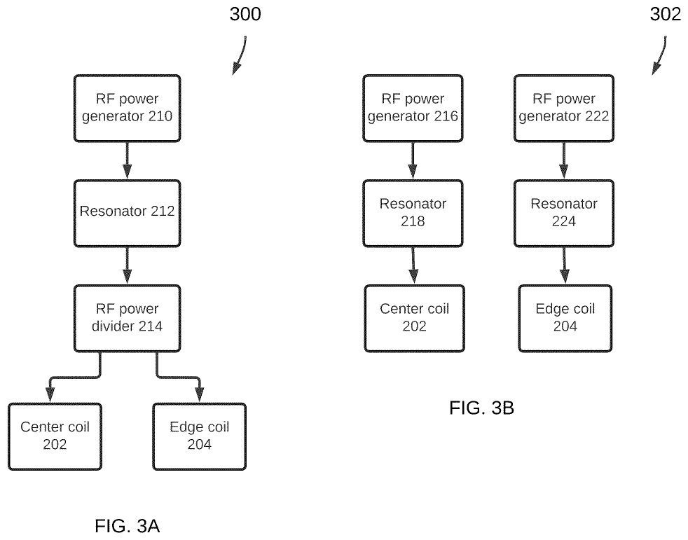

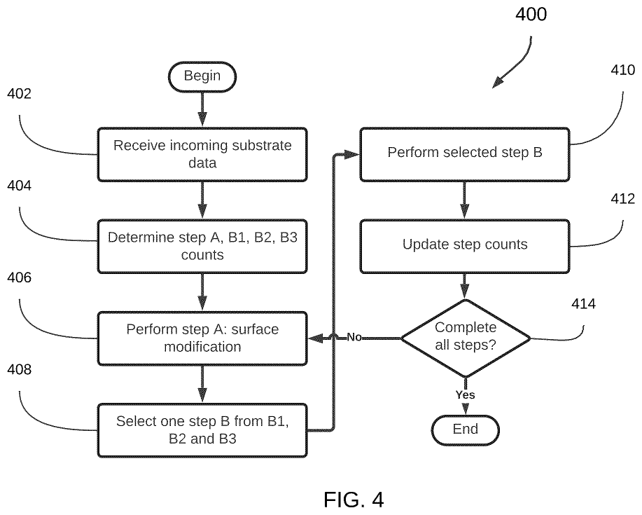

In one embodiment, shown as 300 in FIG. 3A, the center coil 202 and the edge coil 204 are coupled to an RF power generator 210 via a resonator 212. An RF power divider 214 is placed between the resonator 212 and the coils, distributing RF power between the center coil 202 and the edge coil 204. The division ratio may be specified by a process recipe. For example, the center coil 202 may receive 60% of the RF power from the RF power generator 210, while the edge coil 204 receives the remaining 40%.

In another embodiment, shown as 302 in FIG. 3B, the center coil 202 is powered by an RF power generator 216 through a resonator 218, and the edge coil 204 is powered by a separate RF power generator 222 through a resonator 224. This embodiment provides greater flexibility in assigning different RF power levels to the center and edge coils. Additionally, the center and edge coils may receive RF power at different frequencies or with distinct pulsing schemes.

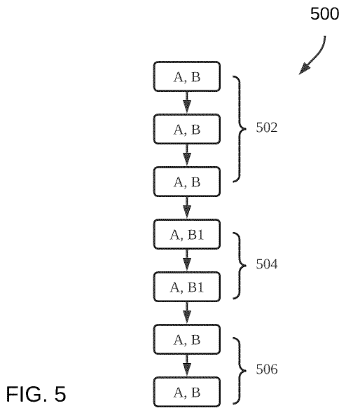

FIG. 4 illustrates an exemplary ALE process 400 with uniformity control mechanisms. The process 400 begins at step 402, where the system controller 128 optionally receives data regarding the incoming substrate. The system controller 128 optionally analyzes this data to determine the required etching performance, such as compensating for substrate nonuniformities. For instance, the system controller 128 may determine that additional etching is needed around the substrate center to correct thickness variations in targeted layers. Based on the required etching performance, the system controller 128 determines the number of cycles for step A and step B in step 404.

A key feature of the present invention is the optional application of different step B sputtering conditions across different ALE cycles, as illustrated exemplarily in Table 1. In step B1, both the center and edge coils (202 and 204) are activated to provide uniform sputtering across the substrate. In step B2, only the center coil 202 is activated, enhancing sputtering at the center of the substrate. In step B3, only the edge coil 204 is activated, focusing sputtering on the substrate edge.

In step 406, step A of the ALE cycle is executed, where chemically active neutrals from the plasma diffuse and modify the substrate surface. This step is ideally a self-limiting process that proceeds once the surface is exposed to the neutral species for a sufficient duration, typically lasting a few hundred milliseconds. To achieve an ideal ALE process, ion bombardment on the substrate surface needs to be eliminated during this surface modification step.

In step 408, the system controller 128 selects one of the step B options (B1, B2, or B3). In step 410, the selected sputtering step is applied to remove the modified layer formed during step 406. Depending on the selected option, the removal of the modified layer may be selective to specific regions of the substrate. In step 412, the system controller 128 updates the step counts. In step 414, the system controller 128 checks whether the ALE process is complete. If so, the process 400 is finished; otherwise, the cycle repeats from step 406.

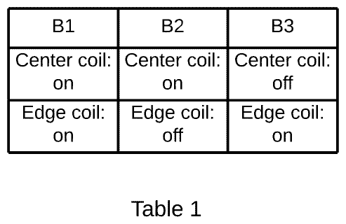

An exemplary ALE process recipe is depicted in FIG. 5, denoted as 500. The recipe includes three cycles (502), each running step A and step B, followed by two cycles (504), each running step A and step B1. The recipe is concluded with two additional cycles (506) of steps A and B. This particular recipe results in increased etching at the substrate center compared to the substrate edge, providing a tailored etching profile to address specific non-uniformities in the substrate.

It should be noted that the TCP plasma source with two concentric coils in this disclosure is for illustration only. More than two concentric coils may be utilized. In some designs, ICP source with concentric coils may also be used. In some other implementations, TCP coils may be combined with ICP coils for the center and the edge, respectively. In still some other implementations, the coils may be placed along a dome on the top of the chamber or along the sidewalls of the chamber. In yet some other designs, the plasma source may also provide options for enhanced or reduced sputtering in selected cycles in specific portions of the substrate. All such variations fall into the scope of the inventive concept of the present invention.

1. A process system, comprising:
a process chamber configured to operate under vacuum conditions;
a chuck located within the process chamber, designed to support a substrate during an ALE process;
a gas distribution unit for introducing process gases into the chamber;
a plasma source for generating a plasma in the chamber, wherein the plasma source includes a center and an edge coil atop a window sealing the chamber; and
a system controller configured to coordinate operations of the process system to perform the ALE process according to a process recipe including multiple cycles, each cycle comprising a surface modification step and a sputtering step, wherein the sputtering step includes multiple options, each option can be selected for a different ALE cycle, wherein the options include selectively turning on or off the center and the edge coil.

2. The system of claim 1, wherein the center and the edge coils are coupled to an RF power generator through a resonator, wherein an RF power divider is utilized to divide the power distribution between the coils.

3. The system of claim 1, wherein the center coil is coupled to a first RF power generator through a first resonator, and the edge coil is coupled to a second RF power generator through a second resonator.

4. The system of claim 1, wherein the options of the sputtering step include:
activating the center and the edge coils;
activating the center coil while the edge coil is deactivated; and
activating the edge coil while the center coil is deactivated.

5. The system of claim 1, wherein the center coil includes one or more than one turns.

6. The system of claim 1, wherein the edge coil includes one or more than one turns.

7. The system of claim 3, wherein the first and the second RF power generators are operated at different frequencies.

8. The system of claim 1, wherein the system controller determines the process recipe based on data of an incoming substrate in addition to an output specification of the ALE process.

9. A method for processing a substrate using an ALE process, comprising:
a. providing a process chamber with a vacuum environment, wherein a plasma can be generated by a plasma source, wherein the plasma source includes a center coil, and an edge coil arranged concentrically;
b. placing the substrate in a chuck of the chamber;
c. performing, by a system controller, a surface modification step;
d. selecting, by the system controller, an option from a plurality of options for a sputtering step;
e. performing, by the system controller, the selected sputtering step; and
f. repeating steps ‘c’ to ‘e’ until the ALE process is complete.

10. The method of claim 9, wherein the options include one with both the center and the edge coils being activated.

11. The method of claim 9, wherein the options include one with the center coil being activated while the edge coil is deactivated.

12. The method of claim 9, wherein the options include one with the center coil being deactivated while the edge coil is activated.

13. The method of claim 9, wherein the center and the edge coils are coupled to a single RF power generator with an RF power divider.

14. The method of claim 9, wherein the center coil is coupled to a first RF power generator, and the edge coil is coupled to a second RF power generator.

15. The method of claim 9, wherein the method further includes a step of generating a process recipe by the system controller based on data of an incoming substrate in addition to an output specification of the ALE process.

16. A method for processing a substrate using an ALE process, comprising:
a. providing a process chamber with a vacuum environment, wherein a plasma can be generated by a plasma source, wherein the plasma source includes a center coil, and an edge coil arranged concentrically;
b. receiving, by a system controller, data about an incoming substrate;
c. generating, by the system controller, an ALE process recipe including ALE cycles, each cycle includes a surface modification step and a sputtering step, wherein the sputtering step includes selectable options for each sputtering step;
d. placing the substrate in a chuck of the chamber; and
e. performing the ALE cycles according to the generated ALE recipe.

17. The method of claim 16, wherein the options include one with both the center and the edge coils being activated.

18. The method of claim 16, wherein the options include one with the center coil being activated while the edge coil is deactivated.

19. The method of claim 16, wherein the options include one with the center coil being deactivated while the edge coil is activated.

20. The method of claim 16, wherein the center coil is coupled to a first RF generator and the edge coil is coupled to a second RF power generator.
